(19) United States
(12) Patent Application Publication
(10) Pub. No.: US 2026/0252066 A1
(43) Pub. Date: Aug. 27, 2026

(54) GENERATION METHOD, SUBSTRATE PROCESSING METHOD, SUBSTRATE PROCESSING APPARATUS, INFORMATION PROCESSING APPARATUS, ARTICLE MANUFACTURING METHOD AND NON-TRANSITORY COMPUTER-READABLE STORAGE MEDIUM

(71) Applicant: CANON KABUSHIKI KAISHA, Tokyo (JP)

(72) Inventors: HIROFUMI FUJII, Tochigi (JP); SHOTA KAYAMORI, Kanagawa (JP); MASAHIRO YOSHIDA, Tochigi (JP)

(21) Appl. No.: 19/546,548

(22) Filed: Feb. 23, 2026

(30) Foreign Application Priority Data
Feb. 25, 2025 (JP) 2025-028240

(51) Int. Cl. G05B 19/418; H10P 72/00

(52) U.S. Cl. CPC G05B 19/41885; H10P 72/0604; G05B 2219/45031

(57) ABSTRACT

A generation method of generating a prediction model for predicting a processing result of a substrate to be processed by a substrate processing apparatus, including generating the prediction model based on apparatus data obtained by processing, by the substrate processing apparatus, a plurality of substrates continuously under the same processing condition and indicating a state of the substrate processing apparatus when substrates up to an Nth (N is a natural number) substrate in the plurality of substrates were processed, and measurement data obtained by measuring a processing result of an (N+1)th substrate in the plurality of substrates.

### BACKGROUND

### Field of the Technology

The present disclosure relates to a generation method, a substrate processing method, a substrate processing apparatus, an information processing apparatus, an article manufacturing method and a non-transitory computer-readable storage medium.

### Description of the Related Art

In recent years, demands on various kinds of processes in a process of manufacturing an article such as a semiconductor device have become increasingly stringent. For example, in an exposure apparatus, since requirements for overlay are stringent, Japanese Patent Laid-Open No. 2023-158946 proposes a technique for reducing overlay errors. Japanese Patent Laid-Open No. 2023-158946 discloses a technique of predicting, using a physical simulation, the distortion of a substrate from data concerning holding of the substrate by a substrate holding unit and calculating a control value for reducing an overlay error from the distortion.

There is no problem in the prior art if the distortion caused by substrate holding is dominant as a factor of the overlay error (a processing result of the substrate), but to further reduce the overlay error, another factor needs to be taken into consideration.

For example, the exposure apparatus includes a driving unit that moves the substrate. Since the driving unit drives using an electromagnetic force as a power source, it generates heat in response to current application, and its driving state (a resistance or the like) changes. To suppress the change of the driving state of the driving unit, generally, measures such as cooling the driving unit is taken, but it is difficult to keep the driving state constant. Hence, a deviation occurs in actual driving with respect to the control value of the driving unit because of the change of the driving state of the driving unit. Also, since the driving state of the driving unit internally changes along with the elapse of time, it is difficult to directly measure it.

Note that in the exposure apparatus, it is difficult to grasp all states in the exposure apparatus including not only the state of the driving unit but also the fluctuation of air in the apparatus. Even if all states are grasped, it is difficult to obtain a degree indicating how these affect the overlay.

### SUMMARY

The present disclosure provides a technique advantageous in generating a prediction model for predicting a processing result of a substrate.

According to one aspect of the present disclosure, there is provided a generation method of generating a prediction model for predicting a processing result of a substrate to be processed by a substrate processing apparatus, including generating the prediction model based on apparatus data obtained by processing, by the substrate processing apparatus, a plurality of substrates continuously under the same processing condition and indicating a state of the substrate processing apparatus when substrates up to an Nth (N is a natural number) substrate in the plurality of substrates were processed, and measurement data obtained by measuring a processing result of an (N+1)th substrate in the plurality of substrates.

Further aspects of the present disclosure will become apparent from the following description of exemplary embodiments with reference to the attached drawings.

### BRIEF DESCRIPTION OF THE DRAWINGS

FIG. 1 is a schematic view illustrating configurations of an exposure apparatus according to an aspect of the present disclosure.

FIG. 2 is a view for explaining an overlay error.

FIG. 3 is a view for explaining a focus error.

FIG. 4 is a view for explaining learning of a prediction model and prediction using the prediction model according to the embodiment.

FIG. 5 is a view for explaining learning of a prediction model and prediction using the prediction model according to the embodiment.

FIG. 6 is a view for explaining learning of a prediction model and prediction using the prediction model according to the embodiment.

FIGS. 7A and 7B are views showing examples of an image of a two-dimensional map of overlay.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

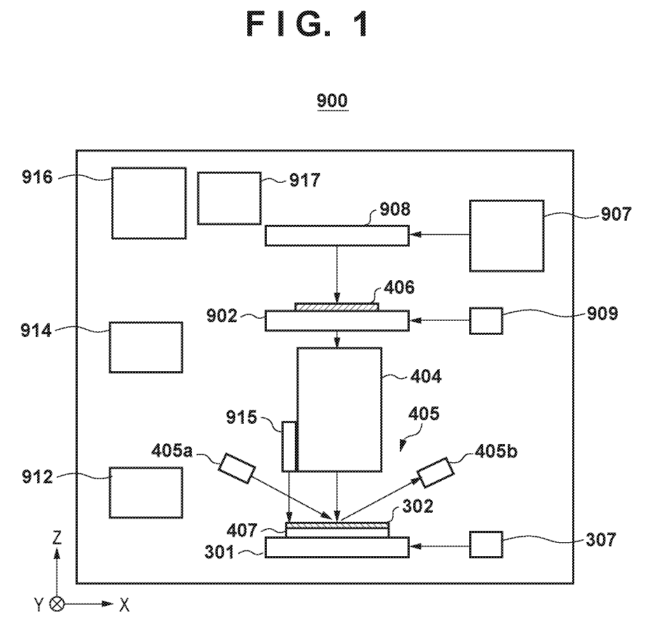

FIG. 1 is a schematic view illustrating configurations of an exposure apparatus 900 according to an aspect of the present disclosure. The exposure apparatus 900 is a lithography apparatus used in a lithography step that is a step for manufacturing an article including a device represented by a semiconductor element. The exposure apparatus 900 is a substrate processing apparatus that exposes a substrate (a wafer or a plate) via an original, thereby forming a pattern on the substrate. The exposure apparatus 900 projects the pattern of the original onto the substrate via a projection optical system and transfers the pattern of the original to the substrate.

Note that in this embodiment, as the substrate processing apparatus, the exposure apparatus 900 will be described as an example, but the substrate processing apparatus broadly includes other processing apparatuses such as an imprint apparatus and a drawing apparatus. The imprint apparatus includes an apparatus that forms an imprint material on a substrate by a mold and forms the pattern of the imprint material on the substrate. Note that the imprint apparatus also includes a planarization apparatus that planarizes a composition on a substrate using a mold with a flat surface. The drawing apparatus includes an apparatus that draws a pattern on a substrate using a charged particle beam (an electron beam, an ion beam, or the like).

In this specification and drawings, directions are indicated on an XYZ coordinate system in which a direction (vertical direction) perpendicular to the surface of a substrate is defined as the Z-axis, and two directions that are parallel to a plane perpendicular to the Z-axis and are perpendicular to each other are defined as the X-axis and the Y-axis. In addition, directions parallel to the X-, Y-, and Z-axes of the XYZ coordinate system are defined as the X, Y, and Z directions, respectively.

In this embodiment, the exposure apparatus 900 is a step-and-scan exposure apparatus (scanner) that exposes a substrate 302 while synchronously scanning an original stage 902 (original 406) and a substrate stage 301 (substrate 302). However, the exposure apparatus 900 may be a step-and-repeat exposure apparatus (stepper) that exposes the substrate 302 in a state in which the original stage 902 and the substrate stage 301 remain still.

As shown in FIG. 1, the exposure apparatus 900 includes a light source unit 907, an illumination optical system 908, the original stage 902, a projection optical system 404, the substrate stage 301, a substrate chuck 407, a control unit 916, and an output unit 917. Also, the exposure apparatus 900 includes an interferometer system 909 on the original side, an interferometer system 307 on the substrate side, a focus measurement unit 405, a substrate conveyance unit 912, an original conveyance unit 914, and an alignment scope 915.

The light source unit 907 includes, for example, a high-pressure mercury-vapor lamp, an ArF excimer laser, a KrF excimer laser, an EUV light source, and the like. The light source unit 907 may be arranged outside a chamber storing constituent elements other than the light source unit 907 of the exposure apparatus 900 or may be stored in one chamber together with the constituent elements other than the light source unit 907 of the exposure apparatus 900.

The illumination optical system 908 illuminates the original 406 with light from the light source unit 907. The original 406 is also called a reticle or a mask. The original 406 has a pattern that should be transferred to the substrate 302 with a photoresist arranged thereon and is held by the original stage 902. The pattern of the original 406 normally includes a plurality of features (for example, a line, a hole, and the like). The original stage 902 holds the original 406 via an original chuck and is driven by, for example, an original driving mechanism including a linear motor and the like.

The projection optical system 404 projects the pattern of the original 406 onto the substrate 302. The pattern of the original 406 is thus transferred to the photoresist arranged on the substrate 302. The projection optical system 404 reduces, for example, the pattern of the original 406 in accordance with a projection magnification (for example, 1/4) and projects it onto the substrate 302. The pattern of the original 406 is sequentially projected onto a plurality of shot regions of the substrate 302, and the plurality of shot regions are sequentially exposed.

The substrate stage 301 is driven by a substrate driving mechanism including a linear motor and the like and can move in the X direction and the Y direction. The substrate chuck 407 is placed on the substrate stage 301 and holds the substrate 302. The substrate stage 301 can be configured to position the substrate chuck 407 concerning the Z direction, the θz direction, the θx direction, and the θy direction. The substrate 302 held by the substrate chuck 407 is positioned via the substrate stage 301 and the substrate chuck 407.

The interferometer system 909 includes a plurality of laser interferometers configured to measure the position of the original stage 902 in the X and Y directions and the postures (θx, θy, θz) of the original stage 902. The interferometer system 307 includes a plurality of laser interferometers configured to measure the position of the substrate stage 301 holding the substrate 302 in the X and Y directions and the postures (θx, θy, θz) of the substrate stage 301. The positions and postures of the original stage 902 and the substrate stage 301 are controlled by the control unit 916 based on the positions and postures measured by the interferometer systems 909 and 307.

The focus measurement unit 405 includes a projection system 405a that projects a plurality of beams onto the substrate 302 by oblique projection, and a light receiving system 405b that receives the plurality of beams reflected by the substrate 302. The light receiving system 405b includes a detection unit that detects the plurality of beams that have entered the light receiving system 405b and provides signals corresponding to these to the control unit 916. The projection system 405a and the light receiving system 405b are arranged across the optical axis of the projection optical system 404. Based on the signals obtained by the focus measurement unit 405, the control unit 916 obtains the position of the substrate 302 in the Z direction and controls movement of the substrate 302 via the substrate stage 301.

The substrate conveyance unit 912 is a mechanism configured to convey the substrate 302. The substrate conveyance unit 912 has, for example, a function of conveying the substrate 302 from a substrate storage container storing the substrate 302 to the substrate stage 301, and a function of conveying the substrate 302 from the substrate stage 301 to the substrate storage container or the like.

The original conveyance unit 914 is a mechanism configured to convey the original 406. The original conveyance unit 914 has, for example, a function of conveying the original 406 from an original storage container storing the original 406 to the original stage 902, and a function of conveying the original 406 from the original stage 902 to the original storage container or the like.

To align the substrate 302 held by the substrate chuck 407, the alignment scope 915 captures an image of a mark (alignment mark) provided on the substrate 302 and obtains a digital image signal. The alignment scope 915 includes an image sensor that outputs an image signal according to a light intensity distribution formed by reflected light from the substrate 302, and an A/D converter that converts the image signal output from the image sensor into a digital image signal. Based on the digital image signal obtained by the alignment scope 915, the control unit 916 obtains the position of the mark on the substrate 302 and aligns the substrate 302 via the substrate stage 301.

The output unit 917 includes, for example, a display device such as a touch panel and an audio output device such as a speaker and is configured to be able to display various kinds of user interfaces (screens) or output various kinds of audio. The output unit 917 may be integrated with the exposure apparatus 900 (in a common housing) or may be formed independently of the exposure apparatus 900 (in another housing).

The control unit 916 comprehensively controls the constituent elements of the exposure apparatus 900, thereby controlling exposure processing of exposing the substrate 302. The control unit 916 is, for example, a Programmable Logic Device (PLD) such as a Field Programmable Gate Array (FPGA), an Application Specific Integrated Circuit (ASIC), a computer with a program installed therein, or an information processing apparatus formed by combining some or all of these. The control unit 916 may be formed by a plurality of processors such as CPUs. Also, the control unit 916 may be arranged in a housing together with other constituent elements of the exposure apparatus 900 or may be arranged outside a housing separately from other constituent elements of the exposure apparatus 900.

The control unit 916 is configured to operate the exposure apparatus 900 while controlling it in accordance with control conditions obtained from a storage unit (not shown) and execute exposure processing (lithography processing) of exposing (processing) the substrate 302 (that is, functions as a processing unit). The control conditions applied to exposure processing include, for example, conveyance conditions defining a conveyance speed, a conveyance path, and the like when conveying the substrate 302 to the substrate stage 301 by the substrate conveyance unit 912. The control conditions applied to exposure processing include, for example, alignment conditions defining an allowable error and the like when aligning the substrate 302 by the substrate stage 301. The control conditions applied to exposure processing include, for example, measurement conditions defining the irradiation time and irradiation timings of a plurality of beams when measuring focus by the focus measurement unit 405. The control conditions applied to exposure processing include, for example, exposure conditions defining the identifier of the original 406, the layout of a plurality of shot regions of the substrate 302, the illumination mode, and the like when exposing the substrate 302.

A detailed example will be described below concerning a case where targets to be evaluated as a processing result by the exposure apparatus 900 are an overlay error and a focus error.

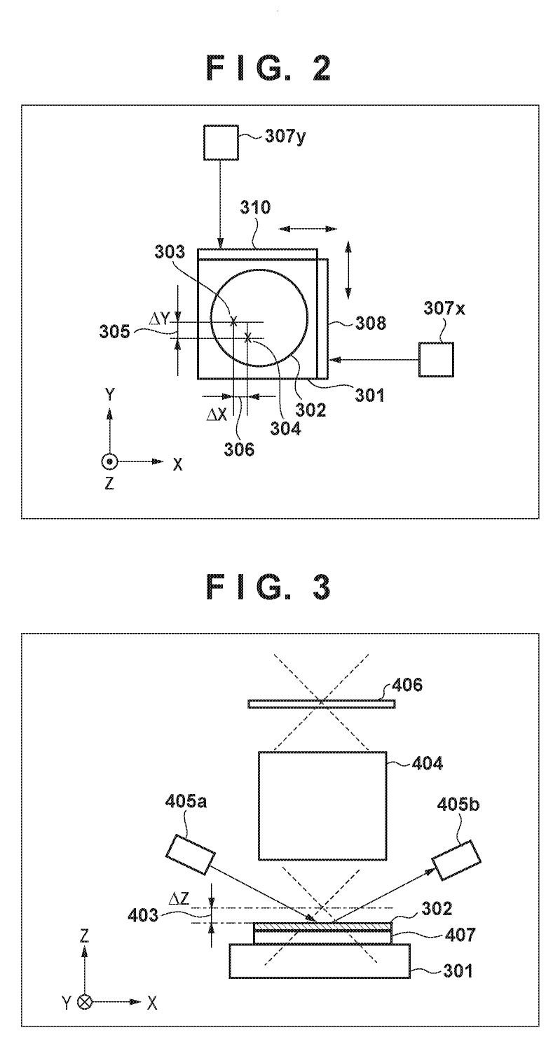

An overlay error will be described with reference to FIG. 2. The substrate 302 is arranged on the substrate stage 301, and with respect to a target position 303 where the feature of the substrate 302 should be transferred (formed), a transfer position 304 of the actually transferred feature includes errors (deviation amounts) ΔX 306 and ΔY 305. If the target position 303 is a target position based on the feature of the lower layer, the errors ΔX 306 and ΔY 305 are understood as alignment errors. If the target position 303 is a target position not based on the feature of the lower layer, the errors ΔX 306 and ΔY 305 are understood as the arrangement errors of the feature transferred to the substrate 302. The error ΔX 306 is an error in the X direction, and the error ΔY 305 is an error in the Y direction. If the overlay error exceeds an allowable range (or a threshold), a connection failure may occur between the feature of the layer (exposed layer) to which the pattern is transferred by the exposure apparatus 900 and the feature of the lower layer.

The position of the substrate stage 301 is measured using an interferometer 307x and an interferometer 307y of the interferometer system 307. On the other hand, it is difficult to measure the transfer position 304 in the exposure apparatus 900. This is because there exist various error factors such as a change of the wavelength of light used in the interferometer system 307, which are derived from the accuracy of an X-axis bar mirror 308 and a Y-axis bar mirror 310 provided on the substrate stage 301, the rotation error of the substrate stage 301, and a change of the environmental temperature.

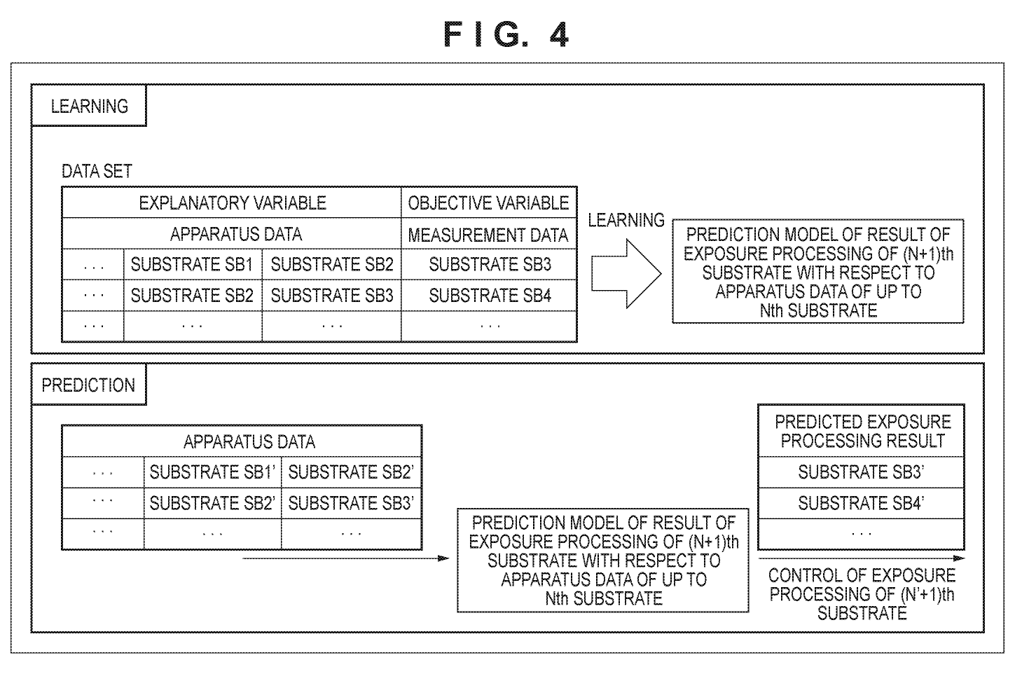

A focus error will be described with reference to FIG. 3. FIG. 3 schematically shows constituent elements associated with focus measurement in the exposure apparatus 900. The distance between the image plane of the projection optical system 404 and the surface (upper surface) of the substrate 302 corresponds to a focus error ΔZ 403. In the exposure apparatus 900, the focus is controlled such that the focus error ΔZ 403 falls within the focal depth. The focus error ΔZ 403 is evaluated by observing the substrate 302 using an SEM or the like after the substrate 302 is exposed.

Apparatus data that affects the focus error ΔZ 403 includes at least one of the following various data. Examples of apparatus data are data indicating a measurement condition in the focus measurement unit 405 and data indicating the control deviation of the substrate stage 301. Other examples of apparatus data are data indicating the environment in which the exposure apparatus 900 is arranged at the time of focus measurement (for example, data such as a temperature, a humidity, and an atmospheric pressure) and data indicating the aberration of the projection optical system 404 at the time of focus measurement.

It is difficult to measure the focus error ΔZ 403 as well because of existence of various error factors in addition to the temporal change of the environment in which the exposure apparatus 900 is arranged.

These error factors include complex factors, but it is possible to grasp the general trend concerning each factor when performing exposure using the same pattern and the same layout (same processing conditions), like the exposure apparatus 900. For example, a heat amount given to the driving mechanism of each stage of the exposure apparatus 900 changes depending on a torque necessary for driving the stage, that is, a temporal change of a current. If the pattern and layout are the same, the heat amount can be considered to be substantially the same. However, since the initial state of each factor changes and the factors complexly interact with each other, direct addition does not suffice, and the factors are difficult to classify.

Hence, in the prior art, instead of solving each factor, a prediction model used to predict the result of exposure processing (the processing result of the substrate 302) is generated by machine learning. More specifically, a prediction model is generated based on apparatus data recorded (stored) as a log in the exposure apparatus 900 (the storage unit of the control unit 916) and measurement data obtained by measuring the corresponding result of exposure processing. The corresponding result of exposure processing is predicted from other apparatus data using the prediction model. However, since this is prediction after exposure processing, it is impossible to improve the result of exposure processing with respect to the current exposure processing.

This embodiment provides a technique advantageous in generating a prediction model for predicting a result of exposure processing of the substrate 302 in a case where the exposure apparatus 900 exposes (processes) a plurality of substrates 302 continuously under the same processing conditions. In this embodiment, concerning measurement data indicating the result of exposure processing of a certain substrate, the relationship with apparatus data when exposure processing of a substrate preceding a certain substrate is performed is learned by machine learning, thereby generating a prediction model. Then, apparatus data at the time of exposure processing of another substrate is input to the prediction model, thereby predicting the result of exposure processing of a substrate next to the other substrate. Additionally, by using the predicted result of exposure processing for control of exposure processing of the next substrate by the exposure apparatus 900, the result of exposure processing can be improved with respect to the current exposure processing.

In this embodiment, the prediction model is generated based on apparatus data indicating the state of the exposure apparatus 900 when substrates up to the Nth substrate in the plurality of substrates 302 were processed and measurement data obtained by measuring the result of exposure processing of the (N+1)th substrate in the plurality of substrates 302. Next, using the prediction model, the processing result of the substrate 302 to be subjected to exposure processing by the exposure apparatus 900 is predicted, and a predicted processing result is obtained. Then, based on the predicted processing result, the control conditions of the exposure apparatus 900 when processing the substrate 302 by the exposure apparatus 900 are decided, and exposure processing of the substrate 302 is performed while controlling the exposure apparatus 900 in accordance with the control conditions. Note that N is a natural number.

Also, in this embodiment, it is assumed that the control unit 916 performs a step of generating a prediction model and a step of obtaining a predicted processing result, that is, the control unit 916 is caused to function as a generation unit configured to generate a prediction model and an obtaining unit configured to obtain a predicted processing result. However, the step of generating a prediction model and the step of obtaining a predicted processing result may be performed by an external information processing apparatus including a generation unit and an obtaining unit.

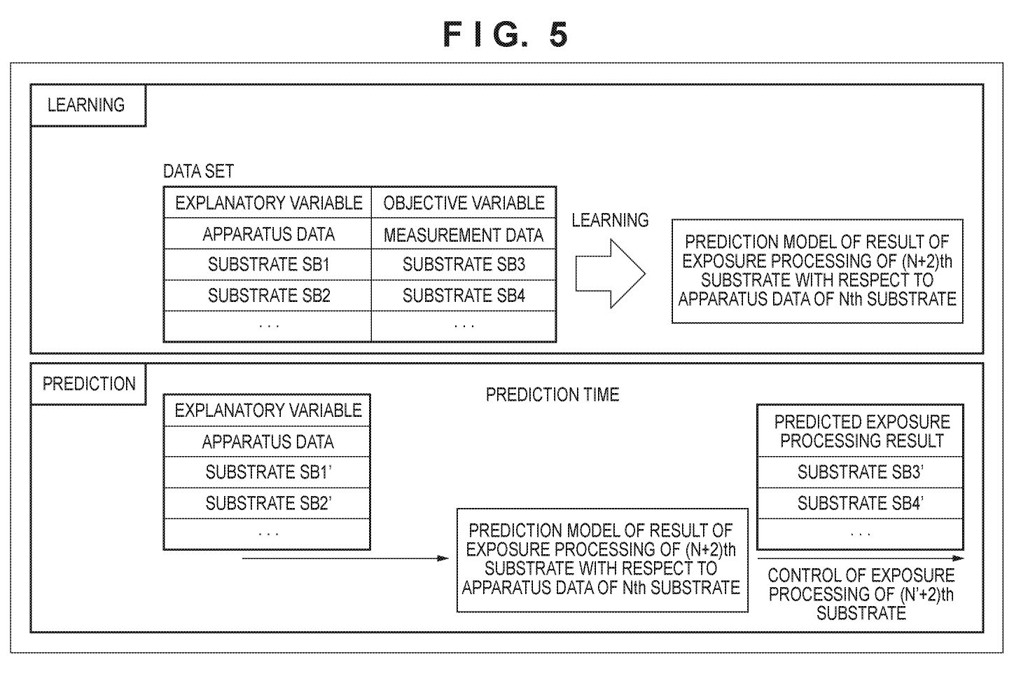

A detailed example for improving overlay, that is, reducing an overlay error as a result of exposure processing of the substrate 302 will be described below. Learning (generation) of a prediction model for predicting an overlay error and prediction of an overlay error using the prediction model in this embodiment will separately be described with reference to FIG. 4.

Learning of a prediction model will be described first. As an objective variable, measurement data obtained by measuring the result of exposure processing of the substrate 302 is considered. The measurement data includes, for example, data concerning at least one of overlay, focus, linewidth uniformity (CD uniformity), and an edge placement error, and here, overlay is used, as described above. Also, as an explanatory variable, apparatus data indicating the state of the exposure apparatus 900 when exposure processing of the substrate 302 was performed, that is, data concerning the apparatus state that changes over time when the exposure apparatus 900 performs exposure processing of a plurality of substrates 302 is considered. The apparatus data includes, for example, data concerning at least one of the position and deviation of the substrate stage 301, the position and deviation of the original stage 902, an alignment result, and the environment in which the exposure apparatus 900 is provided (a temperature, a humidity, an atmospheric pressure, and the like).

As the combination of data sets, for example, the combination of measurement data, that is, overlay of a third substrate SB3 and apparatus data of a second substrate SB2 or a first substrate SB1 is considered. Similarly, the combination of measurement data, that is, overlay of a fourth substrate SB4 and apparatus data of the third substrate SB3 or the second substrate SB2 is considered. Based on the combination of data sets, the relationship between the apparatus data and the measurement data is regressively learned by supervised learning using machine learning, and a prediction model (regression model) is generated. Note that the prediction model may be a polynomial function or may be SVM, GBDT, CNN, or RNN.

In this way, in the learning of a prediction model, a prediction model for predicting overlay that is a result of exposure processing of the (N+1)th substrate with respect to apparatus data when substrates up to the Nth substrate in the plurality of substrates were processed is generated.

Next, prediction using a prediction model will be explained. Prediction using a prediction model is performed when, for example, exposure processing for substrates up to the N'th substrate included in another lot is ended. In this embodiment, using a prediction model, a result of exposure processing of the (N'+1)th substrate is predicted (calculated) from apparatus data when exposure processing of substrates up to the N'th substrate was performed. More specifically, using a prediction model, overlay that is the result of exposure processing of a third substrate SB3' is predicted from apparatus data when exposure processing of a second substrate SB2' or a first substrate SB1' was performed. Similarly, using a prediction model, overlay that is the result of exposure processing of a fourth substrate SB4' is predicted from apparatus data when exposure processing of the third substrate SB3' or the second substrate SB2' was performed. In this way, the result of exposure processing of the (N'+1)th substrate is predicted, and a predicted exposure processing result (predicted processing result) is obtained. When performing exposure processing of the (N'+1)th substrate, the exposure apparatus 900 is feedforward-controlled based on the predicted exposure processing result, thereby improving the result of exposure processing of the (N'+1)th substrate, that is, reducing overlay errors. Note that N' is a natural number.

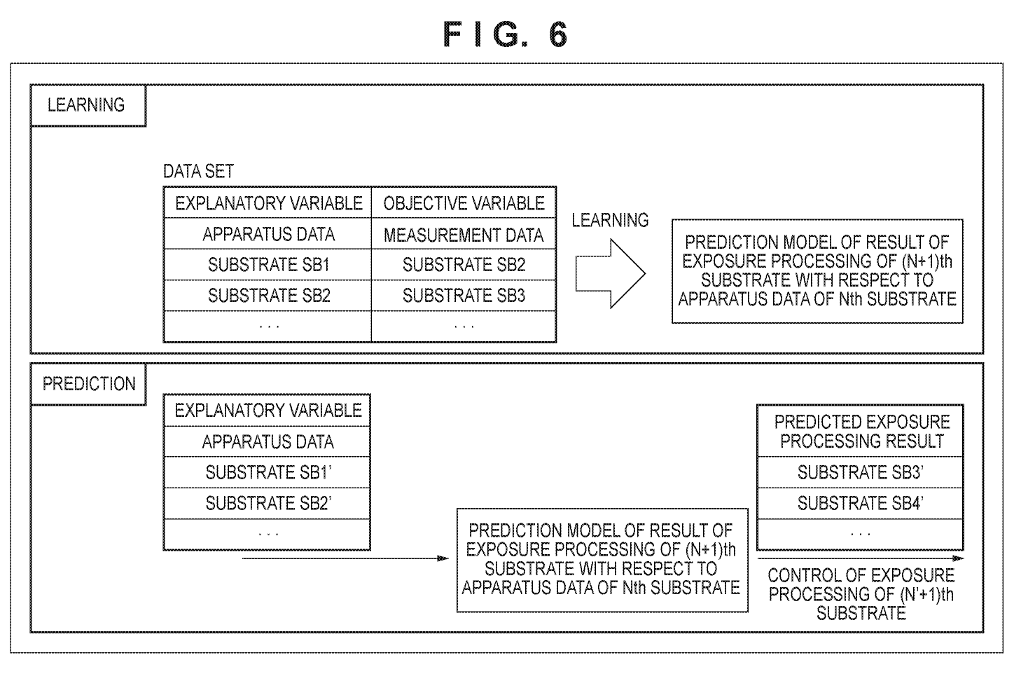

In this embodiment, overlay of the (N'+1)th substrate is predicted, but overlay of a substrate after the (N'+1)th substrate can also be predicted. If time is needed to process apparatus data, and control of exposure processing of the (N'+1)th substrate is delayed, for example, as shown in FIG. 5, overlay of the (N'+2)th substrate may be predicted using the prediction model. In this case, as the combination of data sets for learning of the prediction model, the combination of an overlay of the third substrate SB3 and apparatus data when exposure processing of the first substrate SB1 was performed is considered. In addition, as the combination of data sets for learning of the prediction model, the combination of an overlay of the fourth substrate SB4 and apparatus data when exposure processing of the second substrate SB2 was performed is considered. In prediction using the prediction model, overlay of the third substrate SB3' is predicted from apparatus data when exposure processing of the first substrate SB1' was performed, and overlay of the fourth substrate SB4' is predicted from apparatus data when exposure processing of the second substrate SB2' was performed.

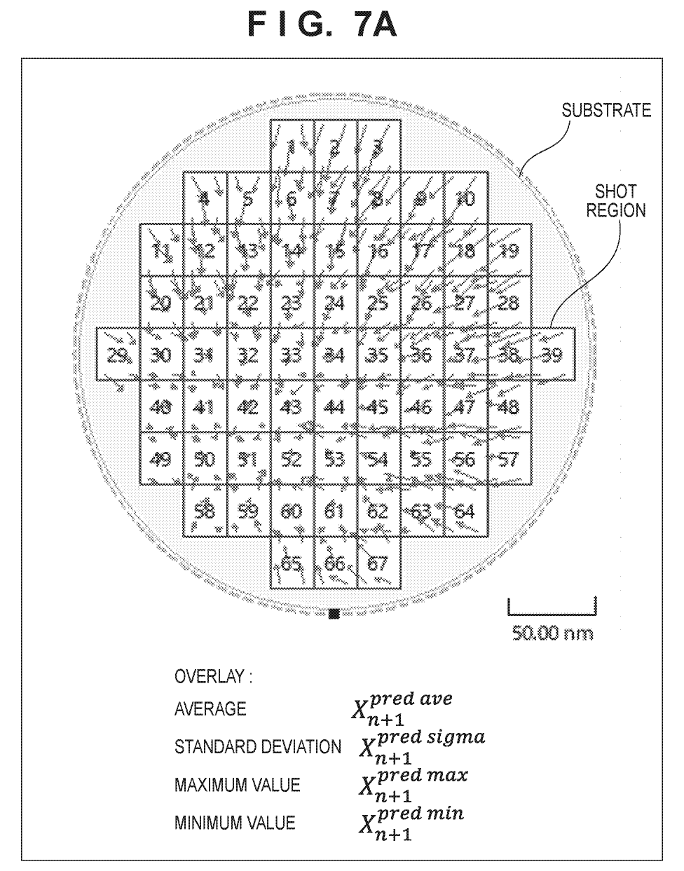

Also, in FIG. 4, the combination of data sets for learning of the prediction model is the combination of a plurality of apparatus data and one measurement data item. In other words, a prediction model is generated based on a plurality of apparatus data when exposure processing of a plurality of substrates up to the Nth substrate was performed and the measurement data of the (N+1)th substrate, but the present disclosure is not limited to this. For example, as shown in FIG. 6, the combination of data sets for learning of the prediction model may be the combination of one apparatus data and one measurement data item such that apparatus data and measurement data are in a one-to-one (single) correspondence. In other words, a prediction model may be generated based on apparatus data when exposure processing of the Nth substrate was performed and measurement data of the (N+1)th substrate. In this case, as the combination of data sets for learning of the prediction model, the combination of an overlay of the second substrate SB2 and apparatus data when exposure processing of the first substrate SB1 was performed is considered. Also, as the combination of data sets for learning of the prediction model, the combination of an overlay of the third substrate SB3 and apparatus data when exposure processing of the second substrate SB2 was performed is considered. In prediction using the prediction model, the overlay of the second substrate SB2' is predicted from apparatus data when exposure processing of the first substrate SB1' was performed, and the overlay of the third substrate SB3' is predicted from apparatus data when exposure processing of the second substrate SB2' was performed.

Also, apparatus data indicating the state of the exposure apparatus 900 may include data outside the exposure apparatus, that is, data concerning the apparatus state outside the control target in the exposure apparatus 900. The apparatus data includes, for example, data concerning the environment of a clean room in which the exposure apparatus 900 is provided. The data concerning the environment of the clean room is the data of the air conditioning temperature, air flow, atmospheric pressure, and humidity of the clean room. These data can be used as apparatus data indicating the future state of the exposure apparatus 900. Hence, as the explanatory variable (apparatus data) for learning of the prediction model, the data concerning the environment of the clean room can be taken into consideration. As information added to the explanatory variable to increase the prediction accuracy, one specific example has been described above. In this regard, an extended idea can be taken, for example, that data before formation of the measurement target of measurement data of the substrate SB3 affects the measurement target of the substrate SB3. Hence, the explanatory variable may include data of processing performed for the substrate SB3 before actual exposure. For example, when performing exposure for the substrate SB3 a plurality of times, the data can include apparatus data of the exposure apparatus at the time of exposure performed before actual exposure and apparatus data of a coating apparatus at the time of application of a resist to be arranged on the substrate SB3, which is performed before exposure.

Also, in this embodiment, when obtaining a predicted exposure processing result by predicting the result of exposure processing of a substrate using a prediction model, a correction amount (control condition) correctable by the exposure apparatus 900 is decided from the predicted exposure processing result. Hence, by measuring the result of actual exposure processing, it is possible to grasp whether the result of exposure processing can correctly be corrected (whether the result of exposure processing is improved). If the result of exposure processing is not correctly corrected, or if there is little effect, it is preferable to relearn (regenerate) the prediction model or stop prediction using the prediction model.

In the process of predicting the result of exposure processing of a substrate, it is assumed that correction is made by the exposure apparatus 900. Hence, the correction amount (control condition) correctable by the exposure apparatus 900 may be obtained by a general affine transformation, and a prediction model may be generated such that the accuracy of the prediction model is optimum for the correction amount. This is advantageous in suppressing degradation of the accuracy of the prediction model caused by a component that cannot be corrected by the exposure apparatus 900.

In this embodiment, the result of exposure processing of the first substrate cannot be predicted. For this reason, the first substrate may be defined as a dummy substrate, and the result of exposure processing of the second and subsequent substrates may be predicted based on apparatus data and measurement data obtained using the dummy substrate.

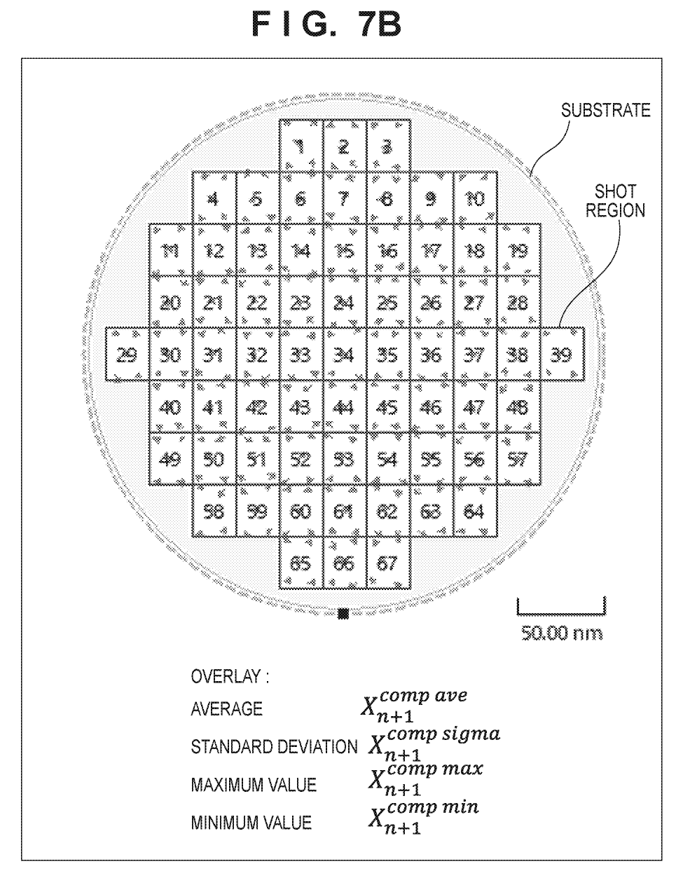

Also, in this embodiment, the result of exposure processing predicted using the prediction model may be displayed on the output unit 917. For example, as shown in FIG. 7A, as the result of exposure processing predicted using the prediction model, overlay is displayed as an image of a two-dimensional map on a substrate basis. In FIG. 7A, overlay is indicated by arrows for each shot region of a substrate. The start point of an arrow indicates the position (prediction point) where the overlay is predicted, the direction of the arrow indicates the direction of overlay, and the length of the arrow indicates the amount (magnitude) of overlay. In addition to the map of overlay, the average, standard deviation, and maximum and minimum values of overlay may be displayed as statistical values. The image of the two-dimensional map of overlay shown in FIG. 7A may be recorded in, for example, the storage unit of the control unit 916.

In addition, the result of exposure processing obtained by feedforward to the exposure apparatus 900 based on the image of the two-dimensional map of overlay shown in FIG. 7A may be displayed on the output unit 917. For example, as shown in FIG. 7B, as the result of exposure processing obtained by feedforward to the exposure apparatus 900, overlay is displayed as an image of a two-dimensional map on a substrate basis. In FIG. 7B, overlay is indicated by arrows for each shot region of a substrate. The start point of an arrow indicates the position (measurement point) where the overlay is measured, the direction of the arrow indicates the direction of overlay, and the length of the arrow indicates the amount (magnitude) of overlay. In addition to the map of overlay, the average, standard deviation, and maximum and minimum values of overlay may be displayed as statistical values. The image of the two-dimensional map of overlay shown in FIG. 7B may be recorded in, for example, the storage unit of the control unit 916.

An article manufacturing method according to the embodiment of the present disclosure is suitable for manufacturing, for example, an article such as a device (a semiconductor element, a magnetic storage medium, a liquid crystal display element, or the like). The manufacturing method includes a step of forming a pattern on a substrate by exposing the substrate using the exposure apparatus 900, a step of processing the substrate with the pattern formed thereon, and a step of manufacturing an article from the processed substrate. The manufacturing method can also include other known processes (oxidation, deposition, vapor deposition, doping, planarization, etching, resist removal, dicing, bonding, and packaging). The article manufacturing method according to this embodiment is advantageous in at least one of the performance, quality, productivity, and production cost of the article, as compared to conventional methods.

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)TM), a flash memory device, a memory card, and the like.

According to the present disclosure, for example, it is possible to provide a technique advantageous in generating a prediction model for predicting a processing result of a substrate.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent application No. 2025-028240 filed on Feb. 25, 2025, which is hereby incorporated by reference herein in its entirety.

What is claimed is:

1. A generation method of generating a prediction model for predicting a processing result of a substrate to be processed by a substrate processing apparatus, comprising:
generating the prediction model based on apparatus data obtained by processing, by the substrate processing apparatus, a plurality of substrates continuously under the same processing condition and indicating a state of the substrate processing apparatus when substrates up to an Nth (N is a natural number) substrate in the plurality of substrates were processed, and measurement data obtained by measuring a processing result of an (N+1)th substrate in the plurality of substrates.

2. The method according to claim 1, wherein in the generating, the prediction model is generated based on a plurality of apparatus data indicating the state of the substrate processing apparatus when each of a plurality of substrates up to the Nth substrate was processed, and the measurement data.

3. The method according to claim 1, wherein in the generating, the prediction model is generated based on apparatus data indicating the state of the substrate processing apparatus when the Nth substrate was processed, and the measurement data.

4. The method according to claim 1, wherein the apparatus data includes data concerning an apparatus state that changes over time when the substrate processing apparatus processes the plurality of substrates.

5. The method according to claim 1, wherein
the substrate processing apparatus includes an exposure apparatus that exposes a substrate via an original, and
the apparatus data includes data concerning at least one of a position and deviation of a substrate stage that holds the substrate, a position and deviation of an original stage that holds the original, an alignment result, and an environment in which the exposure apparatus is provided.

6. The method according to claim 1, wherein the apparatus data includes data concerning an apparatus state outside a control target in the substrate processing apparatus.

7. The method according to claim 1, wherein the apparatus data includes data concerning an environment of a clean room in which the substrate processing apparatus is provided.

8. The method according to claim 1, wherein the measurement data includes data concerning at least one of overlay, focus, linewidth uniformity, and an edge placement error.

9. A substrate processing method of processing a substrate using a substrate processing apparatus, comprising:
obtaining a predicted processing result by predicting, using a prediction model generated by a generation method defined in claim 1, a processing result of the substrate to be processed by the substrate processing apparatus; and
deciding, based on the predicted processing result, a control condition of the substrate processing apparatus when processing the substrate by the substrate processing apparatus and processing the substrate while controlling the substrate processing apparatus in accordance with the control condition.

10. The method according to claim 9, further comprising displaying the predicted processing result as an image of a two-dimensional map.

11. The method according to claim 10, further comprising recording the image.

12. The method according to claim 9, further comprising displaying the processing result of the substrate when the substrate is processed while controlling the substrate processing apparatus in accordance with the control condition decided based on the predicted processing result.

13. The method according to claim 12, further comprising recording the processing result of the substrate when the substrate is processed while controlling the substrate processing apparatus in accordance with the control condition decided based on the predicted processing result.

14. A substrate processing apparatus for processing a substrate, comprising:
an obtaining unit configured to obtain a predicted processing result by predicting, using a prediction model generated by a generation method defined in claim 1, a processing result of the substrate to be processed by the substrate processing apparatus; and
a processing unit configured to decide, based on the predicted processing result, a control condition of the substrate processing apparatus when processing the substrate by the substrate processing apparatus and process the substrate while controlling the substrate processing apparatus in accordance with the control condition.

15. An information processing apparatus for generating a prediction model for predicting a processing result of a substrate to be processed by a substrate processing apparatus, comprising:
a generation unit configured to generate the prediction model based on apparatus data obtained by processing, by the substrate processing apparatus, a plurality of substrates continuously under the same processing condition and indicating a state of the substrate processing apparatus when substrates up to an Nth (N is a natural number) substrate in the plurality of substrates were processed, and measurement data obtained by measuring a processing result of an (N+1)th substrate in the plurality of substrates.

16. An article manufacturing method comprising:
forming a pattern on a substrate using a substrate processing method defined in claim 9;
processing the substrate on which the pattern is formed in the forming; and
manufacturing an article from the processed substrate.

17. A non-transitory computer-readable storage medium storing a program configured to cause a computer to execute a generation method defined in claim 1.
